(19) United States
(12) Patent Application Publication
(10) Pub. No.: US 2006/0125045 A1
(43) Pub. Date: Jun. 15, 2006

(54) Process of fabricating semiconductor devices with isolation and sinker regions containing trenches filled with conductive material

(76) Inventor: Hamza Yilmaz, Saratoga, CA (US)

Correspondence Address: SILICON VALLEY PATENT GROUP LLP, 2350 MISSION COLLEGE BOULEVARD, SUITE 360, SANTA CLARA, CA, 95054, US

(21) Appl. No.: 11/352,633

(22) Filed: Feb. 13, 2006

Related U.S. Application Data
(62) Division of application No. 10/960,505, filed on Oct. 7, 2004.

(51) Int. Cl. H01L 29/00

(52) U.S. Cl. 257/510; 438/221

(57) ABSTRACT

A semiconductor structure includes a trench formed in an epitaxial layer that overlies a semiconductor substrate, the sides of the trench being lined with an oxide layer. The trench is filled with a conductive material, e.g., a metal or heavily-doped polysilicon, and the conductive is in contact with the substrate or a doped region in the substrate or epitaxial layer. The structure expands far less horizontally than conventional diffusions and therefore allows a higher packing density of devices formed in the epitaxial layer. The structure may be used in place of conventional sinkers and isolation diffusions.

This application is a divisional of application Ser. No. 10/960,505, filed Oct. 7, 2004, which is incorporated herein by reference in its entirety.

### FIELD OF THE INVENTION

This invention relates to semiconductor devices and, in particular, to semiconductor devices that contain isolation and/or sinker regions.

### BACKGROUND

In many semiconductor devices it is necessary to form a doped region that extends downward from the surface of the substrate either to electrically isolate a device that is formed in the substrate from other devices or to form a sinker region to connect a metal contact at the surface of the substrate to a submerged layer or region.

FIGS. 1 and 2 illustrate a sinker region and an isolation region, respectively. In FIG. 1, an N+ sinker region 110 is used to make a connection to an N substrate 100 through a P-epitaxial (epi) layer 102, A metal layer 106 contacts the surface of P-epi layer 102 through an opening in a dielectric layer 104. Dielectric layer 104 is often made of borophosphosilicate glass (BPSG). In FIG. 2, an N-type isolation region 130 includes an annular N region 126, which extends downward from the surface of a P-epi layer 122 and merges with an N buried layer 128. N buried layer 128 is formed at the interface between P substrate 120 and P-epi layer 122. Typically, N buried layer 128 is implanted into P substrate 120 and diffuses upward during the growth of P-epi layer 122. Thereafter, annular N region 126 is implanted and diffused downward from the surface of P-epi layer 122 until it merges with the N buried layer 128. As a result, an isolated region 124 is formed in P-epi layer 122. If isolation region 130 is contacted electrically, its voltage can be pulled upward with respect to the voltage of P substrate 120 provided that the junction breakdown voltage of isolation region 130 relative to P substrate 120 is not exceeded. Any device formed within isolated region 124 is likewise pulled upward. For example, isolated region 124 can be biased at 30 V with respect to P substrate 120 while a 5 V NPN transistor operates in isolated region 124.

Conventionally, N+ sinker region 110 and annular N region 126 are formed by implanting a shallow dopant through the surface of the epi layer and diffusing the dopant downward. Unfortunately, a necessary consequence of this process is to increase the lateral dimension of N+ sinker region 110 and annular N region 126. It is well known that the lateral spreading of a dopant is equal to approximately 0.8 times its vertical diffusion. Thus the diffusion process uses up valuable space on the substrate and reduces the packing density of the devices formed in the substrate. Ideally, N+ sinker region 110 and annular N region 126 would have very narrow, vertical structures, but this type of configuration is difficult to obtain using the normal diffusion process.

### SUMMARY

This problem is solved by this invention, according to which a trench is formed in a semiconductor substrate, for example by etching, and a dielectric layer, for example silicon dioxide, is formed on the sidewalls and of the trench. The trench is then filled with a conductive material, such as doped polysilicon or a metal. Since trenches as narrow as 0.25 μm, for example, can be etched in semiconductor materials, the lateral dimension of the isolation or sinker region can be kept very small. There is no lateral diffusion of dopants to be concerned about.

In one embodiment, the trench is formed by reactive ion etching (RIE) and an oxide layer is thermally grown on the sidewalls and floor of the trench. A highly directional etching process such as RIE is then used to move the oxide from the floor of the trench without appreciably removing the oxide layer from the sidewalls of the trench. The trench is then filled with polysilicon that has been doped with an impurity such as phosphorus and is therefore highly conductive. This results in a highly vertical structure that can be used to make an electrical contact between a metal layer overlying the surface of the semiconductor substrate, for example, and a layer or region submerged in the substrate. In one embodiment, the “substrate” includes an epitaxial layer formed on the surface of a single-crystal semiconductor substrate, and the structure extends through the epitaxial layer to the single-crystal substrate. Alternatively, the trench can be formed in the shape of a closed loop so as to create an isolated pocket of semiconductor material that extends downward from the surface of the substrate.

### BRIEF DESCRIPTION OF THE DRAWINGS

FIG. 1 shows a cross-sectional view of a conventional sinker region.

FIG. 2 shows a cross-sectional view of a conventional isolation region.

FIGS. 3A-3H illustrate the steps of a process that can be used to form a sinker or isolation region according to this invention.

FIGS. 4A and 4B are cross-sectional views of an N-epitaxial (epi) based bipolar complementary double-diffused metal-oxide-silicon (BCDMOS) arrangement.

FIG. 4C is a plan view of the device shown in FIG. 4B.

FIGS. 5A and 5B are cross-sectional views of a BCDMOS arrangement formed in a P-epi layer grown on a P substrate.

FIG. 6 is a cross-sectional view of a bipolar NPN transistor (NPN) that includes a silicon-germanium base region and an emitter formed of a polysilicon layer.

FIGS. 7A and 7B cross-sectional views of a high-voltage lightly-doped drain complementary MOSFET (LDMOSFET) formed in an N-epi layer.

FIG. 8A is a cross-sectional view of a “quasi-vertical” NMOS formed in an N-epi layer.

FIG. 8B is a plan view of the NMOS shown in FIG. 8A.

FIG. 8C is an alternative plan view of the NMOS shown in FIG. 8A.

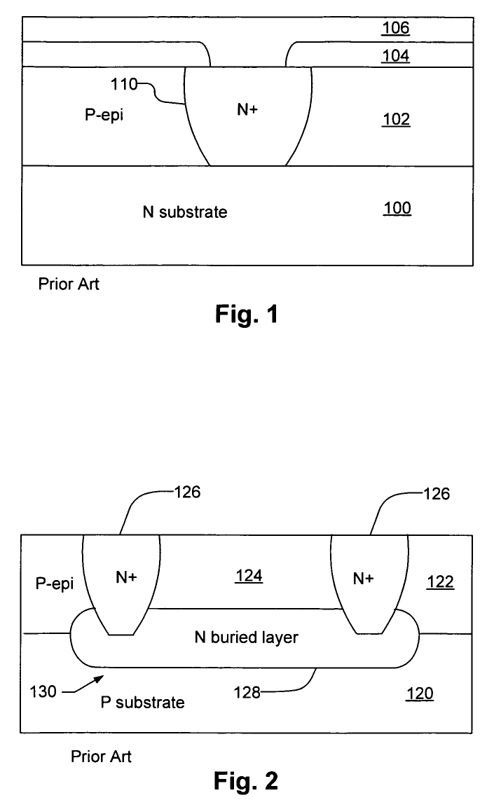

### DETAILED DESCRIPTION

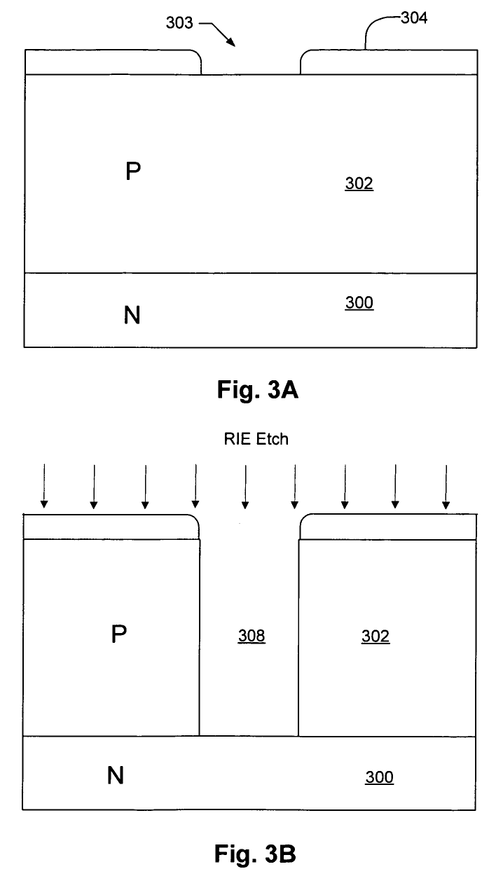

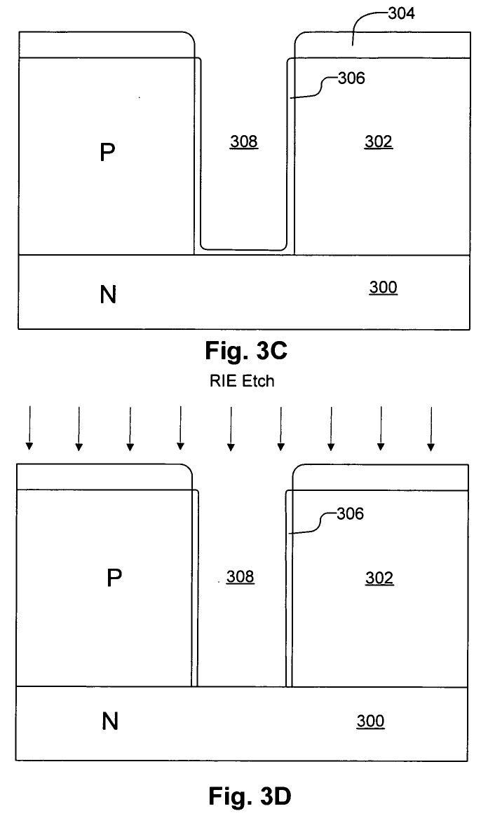

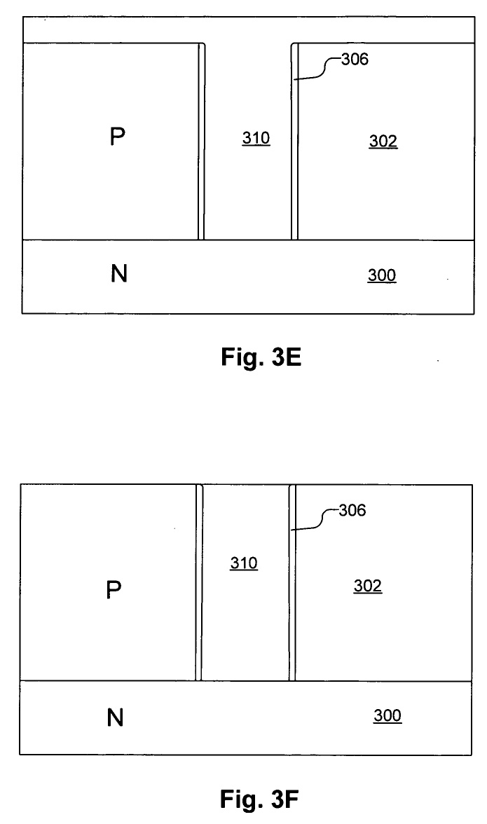

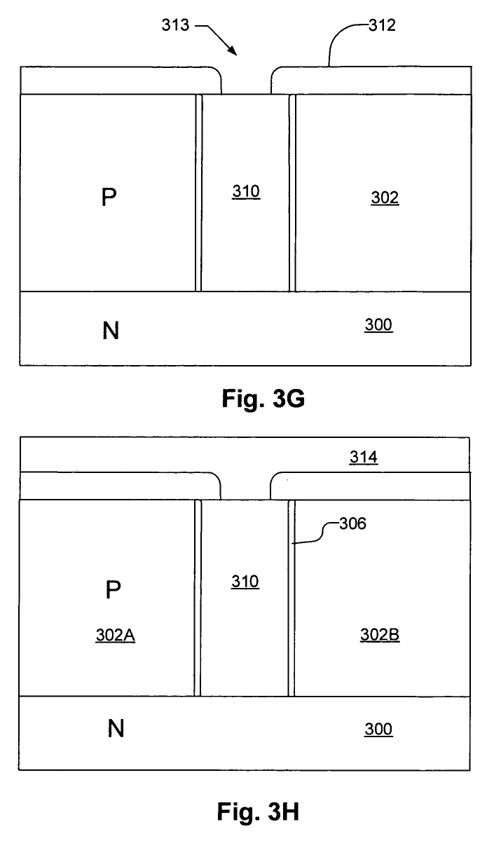

FIGS. 3A-3H illustrate a process that can be used to form a sinker or isolation region according to this invention.

Referring to FIG. 3A, the process begins with a P layer 302, which overlies an N layer 300. P layer 302 and N layer 300 are intended to be generic representations of various types of layers and regions. For example, P layer 302 could be an epitaxial (epi) layer and N layer 300 could be a single-crystal substrate. Alternatively, P layer 302 could be a P-epi layer and N layer 300 could be a buried N layer. Moreover, in some embodiments, layers 300 and 302 have the same conductivity type.

The process begins with an etch mask being formed on the surface of P layer 302. In FIG. 3A, the etch mask includes a layer 304, which could be a silicon nitride layer. An opening 303 is formed in layer 304 by conventional means.

As shown in FIG. 3B, a reactive ion etch (RIE) is then performed. This is a highly directional etch that removes the portion of P layer 302 that is directly below opening 303 to form a trench 308. As indicated, the sidewalls of trench 308 are vertical and trench 308 does not extend laterally beyond the lateral extent of opening 303. For example, if P layer 302 is 10 μm thick, trench 308 could be 0.5-1.0 μm wide.

As shown in FIG. 3C, P layer 302 and N layer 300 are heated to form a layer 306 of silicon dioxide on the sidewalls and floor of trench 308. Oxide layer 306 could be from 0.01 to 0.2 μm thick, for example.

As shown in FIG. 3D, a second RIE etch performed. Since this is a highly directional (vertical) process, it removes the portion of oxide layer 306 on the floor of trench 308 but leaves oxide layer 306 on the sidewalls of trench 308.

As shown in FIG. 3E, a polysilicon layer 310 is deposited, filling trench 308 and flowing over the surface of P layer 302. Polysilicon layer 310 is doped with an N-type dopant such as phosphorus. The doping of polysilicon layer 310 can be performed by an ion implantation followed by diffusion or by incorporating a dopant species into the polysilicon in situ during deposition. The doping concentration of polysilicon layer 310 can be in the range of 1×10¹⁸ to 1×10²⁰ atoms/cm³. With a doping concentration in this range, polysilicon layer 310 is highly conductive. Alternatively, a metal such as nickel, copper, Ti/TiN with aluminum or tungsten can be deposited in place of polysilicon. Since oxide layer 306 has been removed from the floor of trench 308, N+ polysilicon layer 310 makes a low-barrier contact with N layer 300.

Next, as shown in FIG. 3F, polysilicon layer 310 is planarized by etching down or by chemical-mechanical polishing (CMP) so that the top surface of polysilicon layer 310 is approximately coplanar with the top surface of P layer 302.

Finally, polysilicon 310 is electrically contacted from above. This can be done as shown in FIGS. 3G and 3H. As shown in FIG. 3G, a dielectric layer 312 is deposited on the surface of P layer 302 and polysilicon layer 310 and masked and etched to form an opening 313. Dielectric layer 312 could be silicon nitride, silicon oxide or borophosphosilicate glass (BPSG), for example. Finally, as shown in FIG. 3H, a metal layer 314 of Ti/W, Ti/TiN, nickel or copper, for example, is then deposited over dielectric layer 312 and forms an ohmic contact with polysilicon layer 310 through opening 313. If a metal is used instead of doped polysilicon to fill the trench, the side wall oxide should be formed and the trench should be filled with metal after all of the high-temperature processes have been completed.

The result, then, is a highly constrained (horizontally) structure that forms an electrical contact between metal layer 314 and N layer 300 while electrically isolating a region 302A of P layer 302 from a region 302B of P layer 302, as shown in FIG. 3H. Moreover, unlike conventional diffused sinkers and isolation regions, thermal processing that occurs following the formation of the structure has no effect on the lateral dimension of the structure.

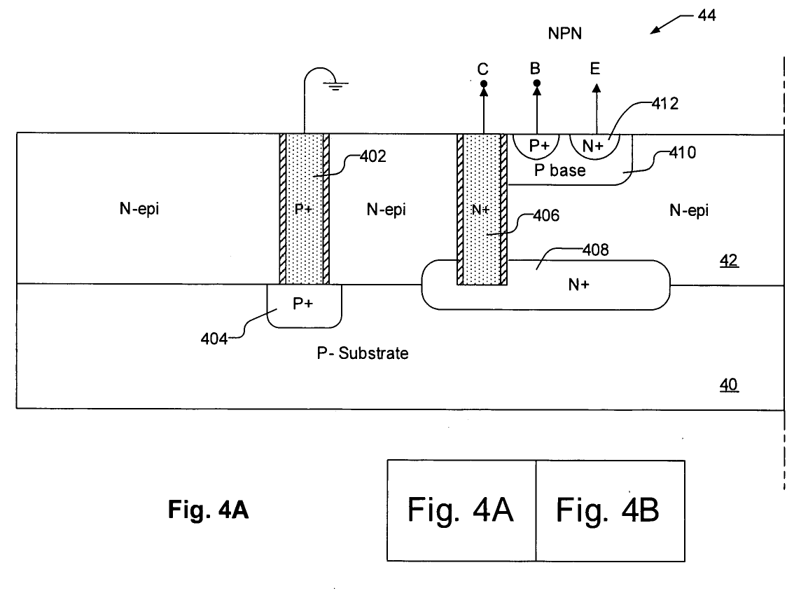

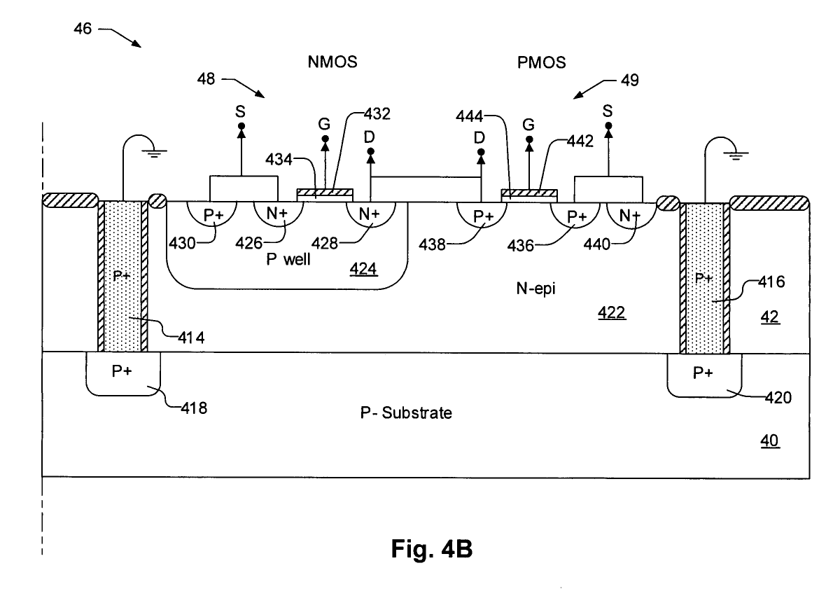

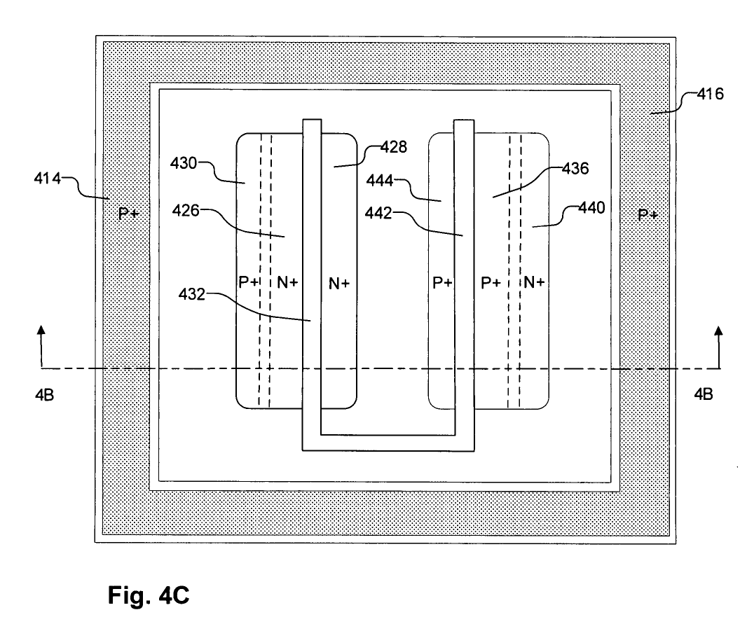

A wide variety of semiconductor devices and combinations of semiconductor devices can be constructed using the broad principles of this invention. Several of them are shown in FIGS. 4-8 but it should be understood that the devices shown in FIGS. 4-8 are illustrative only.

FIGS. 4A and 4B are cross-sectional views of an N-epitaxial (epi) based bipolar complementary double-diffused metal-oxide-silicon (BCDMOS) arrangement. The arrangement is formed in an N-epi layer 42 that is grown on top of a P substrate 40.

FIG. 4A shows a bipolar NPN transistor (NPN) 44. NPN 44 is formed in a region of N epi layer 42 that is isolated from a remaining region of N-epi layer 42 by an P+ isolation structure 402 that is fabricated in accordance with this invention. P+ isolation structure 402 extends from the top surface of N-epi layer to the interface between P substrate 40 and N-epi layer 42. Ohmic contact between P+ isolation structure 402 and P substrate 40 is made via a P+ region 404 that is preferably implanted into P substrate 40 before N-epi layer 42 is grown.

NPN 44 includes an N+ sinker 406 that terminates in an N+ region 408. Together N+ sinker 406 and N+ region 408 and an adjoining portion of N-epi layer 42 form the collector of NPN 44. A P region 410 forms the base of NPN 44, and an N+ region 412 forms the emitter of NPN 44. Metal contacts (not shown) to the collector, base and emitter of NPN 44 are formed in a conventional manner at the top surface of N-epi layer 42.

FIG. 4B shows a CMOS 46, which includes an NMOS 48 and a PMOS 49. CMOS 46 is isolated from the remainder of N-epi layer 42 by P+ isolation structures 414 and 416. P+ isolation structures 414 and 416 extend from the top surface of N-epi layer 42 and terminate in P+ regions 418 and 420. It will be understood that P+ isolation regions 414 and 416 could be part of a single isolation structure that surrounds an isolated region 422 of N-epi layer 42, containing NMOS 48 and PMOS 49.

NMOS 48 and PMOS 49 can be fabricated in a conventional manner. NMOS 48 is formed in a P well 424. NMOS 48 includes an N+ source region 426 and an N+ drain region 428. N+ source region 426 is shorted to P well 424 via a P+ region 430. A polysilicon gate 432 overlies a channel region of P well 242 and is separated from N-epi layer 42 by a gate oxide layer 434.

PMOS 49 includes a P+ source region 436 and an P+ drain region 438. P+ source region 436 is shorted to N-epi layer 42 via an N+ region 440. A polysilicon gate 442 overlies a channel region of isolated region 422 and is separated from N-epi layer 42 by a gate oxide layer 444.

FIG. 4C is a plan view showing the layout of the CMOS shown in FIG. 4B.

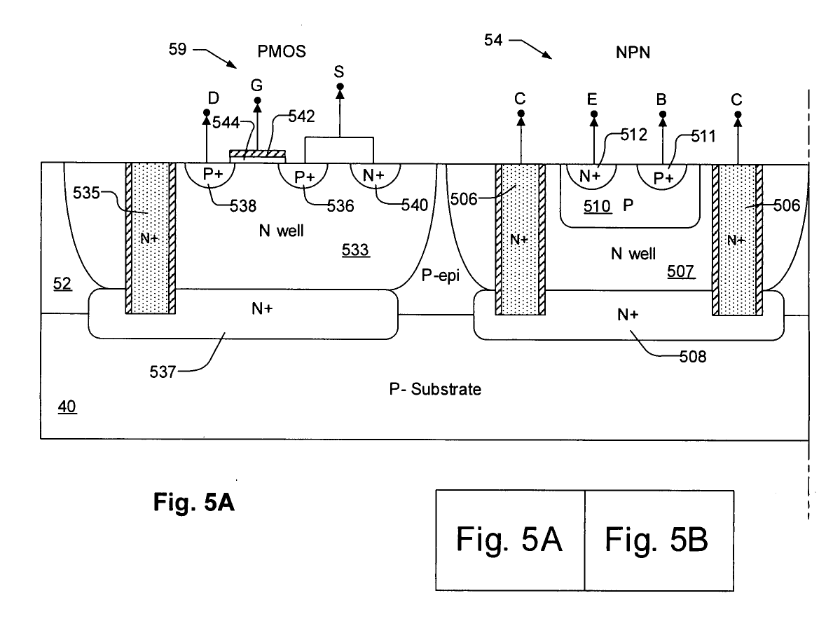

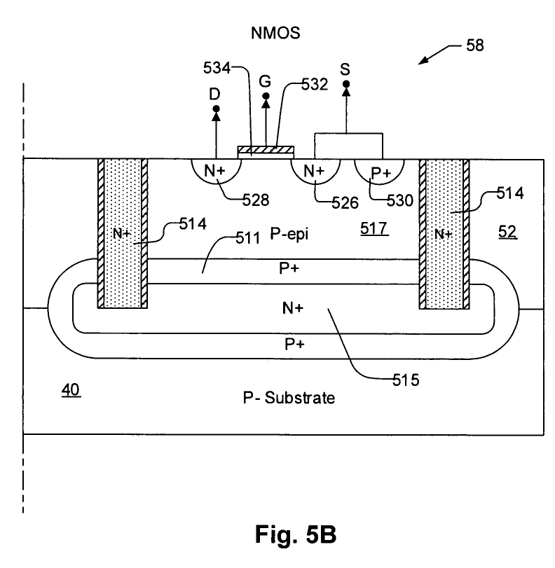

FIGS. 5A and 5B are cross-sectional views of a P-epi based BCDMOS arrangement, which is formed in a P-epi layer 52 that is grown on top of P substrate 40.

The BCDMOS arrangement includes a bipolar NPN transistor 54, an NMOS 58 and a PMOS 59. PMOS 59 is formed in an N well 533, which extends downward from the surface of P-epi layer 52 to an N+ buried layer 537. N+ buried layer 537 may be formed in a conventional manner by implanting an N-type dopant into P substrate 40 before P-epi layer 52 is thermally grown. An N+ sinker 535, formed in accordance with this invention, extends downward from the surface of P-epi layer 52 to N+ buried layer 537. N+ sinker 535 is preferably formed after the formation of N well 533.

Within N+ well 533 are a P+ source region 536, a P+ drain region 538 and an N+ body contact region 540. A polysilicon gate 542, separated from P-epi layer 52 by a gate oxide layer 544, overlies a channel region of N well 533. P+ source region 536 and N+ body contact region are shorted together by a metal layer (not shown) over the surface of P-epi layer 52. PMOS 59 is “self-isolated” from P-epi layer 52 and P substrate 40 so long as N+ buried layer 537 and N well 533 are biased positive in relation to P substrate 40. N+ buried layer 537 and N well 533 can be biased at a desired voltage by means of a metal contact (not shown) to N+ sinker 535.

Bipolar NPN transistor (NPN) 54 has a collector that includes an N well 507 and an N+ buried layer 508. The base of NPN 54 includes a P well 510 and a P+ base contact region 511. An N+ region 512 forms the emitter of NPN 54. The base and emitter of NPN 54 are laterally surrounded by an N+ isolation structure 506, which extends downward to N+ buried layer 508 and is formed in accordance with this invention. NPN 54 is self-isolated from P substrate 40 so long as its collector is biased positive in relation to P substrate 40.

NMOS 58 is formed in an isolated region 517 of P-epi layer 52. Isolated region 517 is isolated from P substrate by a P+ buried layer 511, an N+ buried layer 515 that is formed within P+ buried layer 511, and an N+ isolation structure 514 that is formed in accordance with this invention. N+ isolation structure 514 extends downward from the surface of P-epi layer 52 into N+ buried layer 515 and laterally surrounds isolated region 517. NMOS 58 includes an N+ source region 526 and an N+ drain region 528. N+ source region 526 is shorted to isolated region 517 via a P+ body contact region 530. A polysilicon gate 532 overlies a channel region of isolated region 517 and is separated from P-epi layer 52 by a gate oxide layer 534.

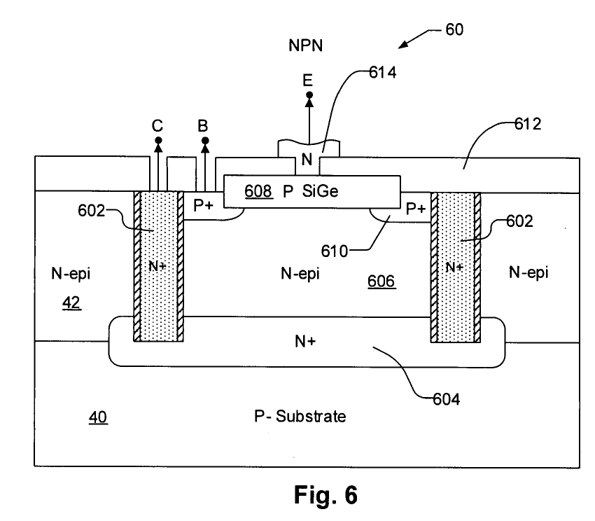

FIG. 6 is a cross-sectional view of a bipolar NPN transistor (NPN) 60 that includes a P-type silicon-germanium base region and an emitter formed of a polysilicon layer. NPN 60 is formed in N-epi layer 42. A silicon dioxide (oxide) layer 612 is formed on the top surface of N-epi layer 42, and is patterned and etched to form openings as shown in FIG. 6. The collector of NPN 60 includes an isolated region 606 of N-epi layer 42, an N+ buried layer 604 and an N+ isolation structure 602 that is formed in accordance with this invention. N+ isolation structure 602 is contacted through an opening in oxide layer 612 and extends downward into N+ buried layer 604. The base of NPN 60 includes a P-type silicon-germanium layer 608 and a P+ base contact region 610. A silicon-germanium layer can be grown on the surface of N-epi layer 42 in an opening (not shown) in an oxide layer, after which the germanium diffuses downward into N-epi layer 42 to form silicon-germanium layer 608. N+ isolation structure 602 laterally surrounds isolated region 606 and silicon-germanium layer 608.

The emitter of NPN 60 is formed by a polysilicon layer 614 that is heavily doped with an N-type material, such as arsenic, phosphorus or antimony, to a doping concentration in the range of 1×10¹⁹ to 1×10^{20 cm-}³ (which is the upper limit of doping in polysilicon). Polysilicon layer 614 is initially deposited in the opening in oxide layer 612 and overlaps the top surface of oxide layer 612. Polysilicon layer 614 is then masked and etched so that polysilicon layer 614 is limited to the vicinity of the opening in oxide layer 612, as shown in FIG. 6. NPN 60 is isolated so long as the collector is biased positive relative to P substrate 40.

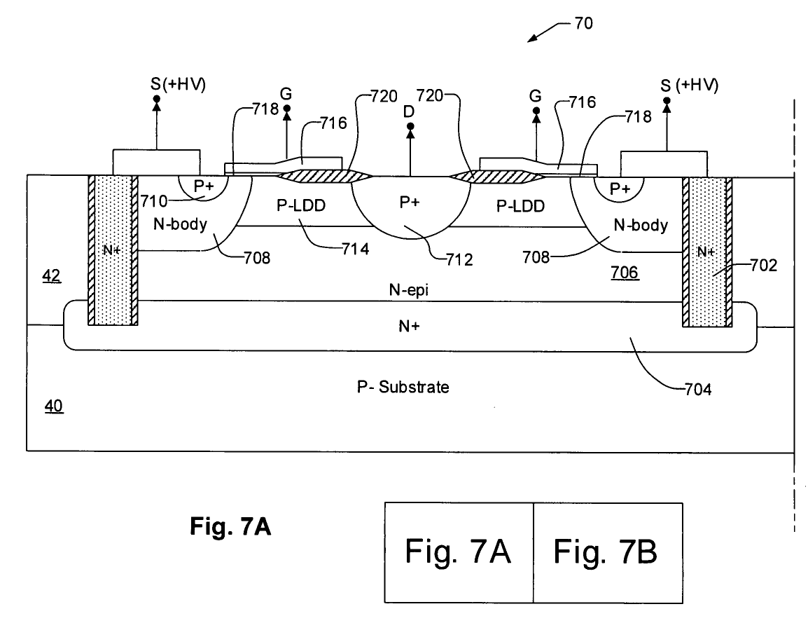

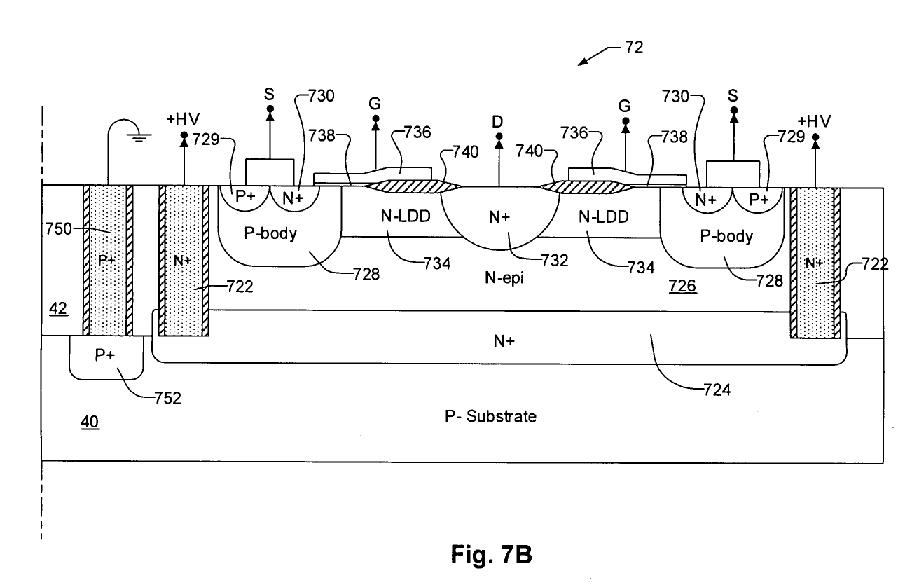

FIGS. 7A and 7B cross-sectional views of a high-voltage lightly-doped drain complementary MOSFET (LDMOSFET) formed in N-epi layer 42. The LDMOSFET includes a lightly-doped drain PMOS (LDD-PMOS) 70, shown in FIG. 7A, and a lightly-doped drain NMOS (LDD-NMOS) 72, shown in FIG. 7B.

Referring first to FIG. 7A, LDD-PMOS 70 is formed inside an isolation structure that includes an N+ buried layer 704 and an N+ isolation structure 702, formed in accordance with this invention, which extends downward into N+ buried layer 704. Together, N+ buried layer 704 and N+ isolation structure 702 enclose an isolated region 706 of N-epi layer 42. LDD-PMOS 70 includes a P+ source region 710 and a P+ drain region 712. In this embodiment, P+ drain region 712 is located at the center of isolated region 706; the other components of LDD-PMOS are fabricated in the form of closed figures (circles, squares, hexagons, etc.) that laterally surround P+ drain region 712. P+ source region 710 is formed within an N-body region 708, and a channel region of N-body region 708 underlies a polysilicon gate 716 that is separated from N-epi layer 42 by a gate oxide layer 718. Gate 716 “steps up” over a thick oxide layer 720, and underlying a portion of gate oxide layer 718 and thick oxide layer 720 is a lightly-doped drain extension (P-LDD) 714 that separates the channel region of N-body region 708 from P+ drain region 712. Thick oxide layer 720 may be formed by a local oxidation of silicon (LOCOS) process; hence, both ends of thick oxide layer 720 have the well-known “bird's beak” formation. P+ source region 710 is shorted to N-body region 708 via N+ isolation structure 702. In this embodiment, P+ source region 710 and N-body region 708 are biased at a high-voltage, and current flows through the channel in N-body region 708 and P-LDD 714 to P+ drain region 712.

Referring to FIG. 7B, LDD-NMOS 72 is formed inside an isolation structure that includes an N+ buried layer 724 and an N+ isolation structure 722, formed in accordance with this invention, which extends downward into N+ buried layer 724. Together, N+ buried layer 724 and N+ isolation structure 722 enclose an isolated region 726 of N-epi layer 42. LDD-NMOS 72 includes an N+ source region 730 and an N+ drain region 732. N+ drain region 732 is located at the center of isolated region 726; the other components of LDD-PMOS are fabricated in the form of closed figures (circles, squares, hexagons, etc.) that laterally surround N+ drain region 732. N+ source region 730 is formed within a P-body region 728, and a channel region of P-body region 728 underlies a polysilicon gate 736 that is separated from N-epi layer 42 by a gate oxide layer 738. Gate 736 “steps up” over a thick oxide layer 740, and underlying a portion of gate oxide layer 738 and thick oxide layer 740 is a lightly-doped drain extension (P-LDD) 734 that separates the channel region of P-body region 728 from N+ drain region 732. Thick oxide layer 740 may be formed by a local oxidation of silicon (LOCOS) process. N+ source region 730 is shorted to P-body region 708 via a P+ body contact region 729. Current flows through the channel in N-body region 708 and P-LDD 714 to P+ drain region 712.

In this embodiment, a P+ sinker 750 extends downward from the surface of N-epi layer 42 to the interface between N-epi layer 42 and P substrate 40. A P+ region 752 ensures a good ohmic contact between P+ sinker 750 and P substrate 40.

P substrate 40 is grounded via P+sinker 750, and N+ isolation structure 722 and N+ buried layer 724 are biased at a high-voltage, causing LDD-NMOS 72 to “float” at the same high potential above ground.

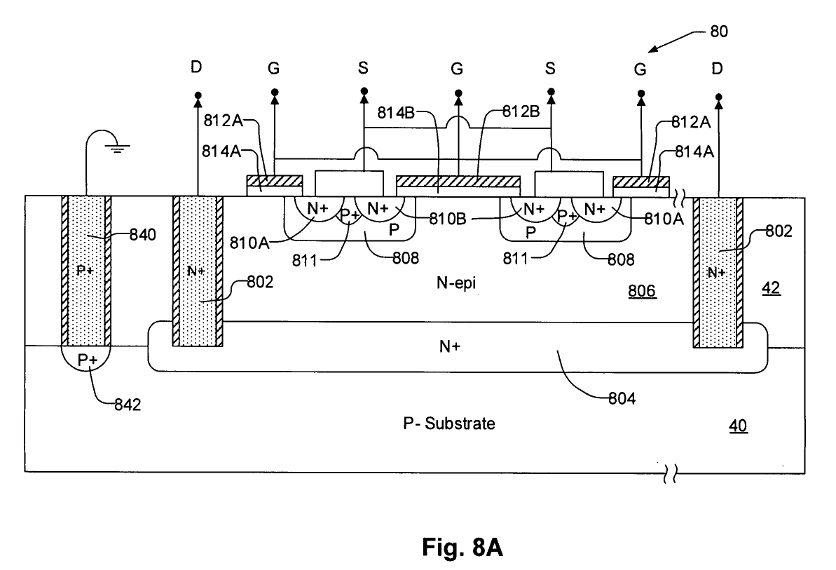

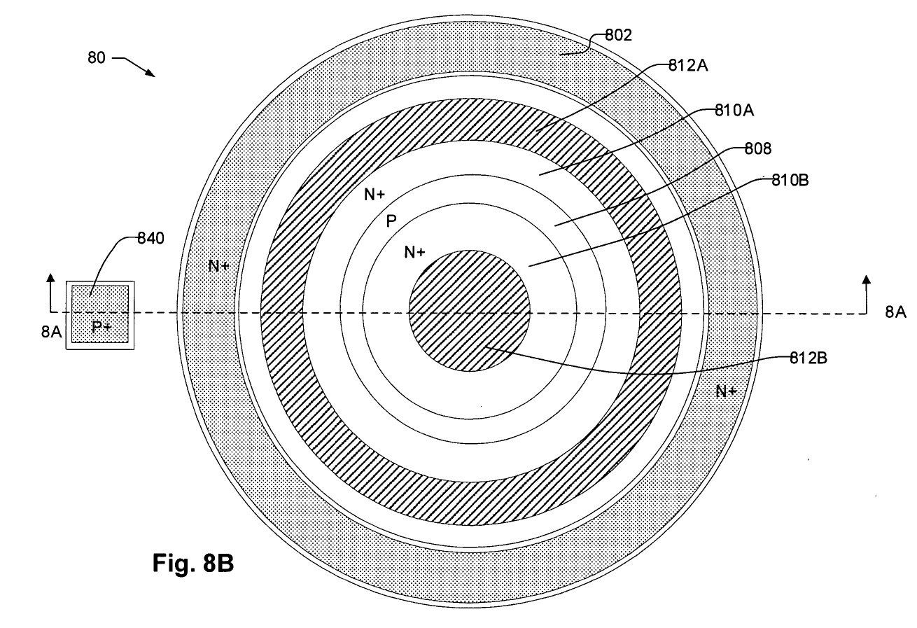

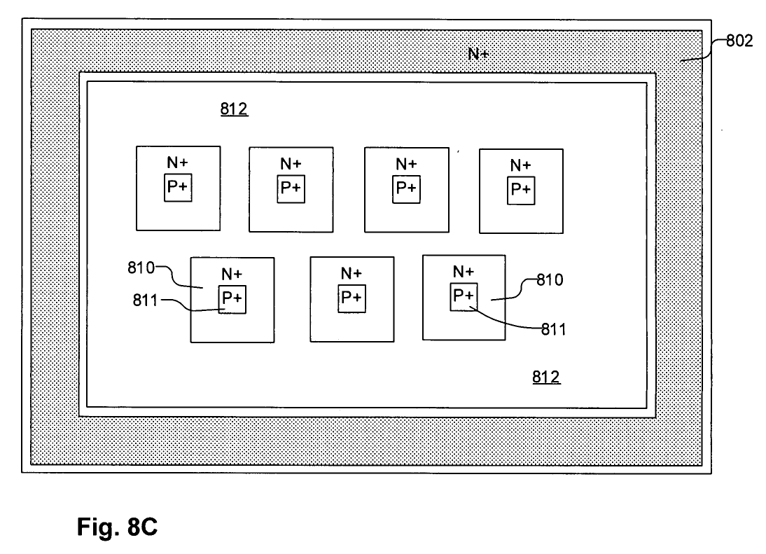

FIG. 8A is a cross-sectional view of a “quasi-vertical” NMOS 80, formed in N-epi layer 42. NMOS 80 is formed within an isolated region 806 of N-epi layer 42 that is isolated from P substrate 40 by an N+ buried layer 804 and an N+ isolation structure 802, formed in accordance with this invention. N+ source regions 810A and 810B are formed at the surface of N-epi layer 42, within a P-body region 808. A P+ body contact region is in electrical contact with a metal layer (not shown) to provide an ohmic contact with P-body region 808. Polysilicon gates 812A and 812B overlie channel regions of P-body region 808 and are separated from N-epi layer 42 by gate oxide layers 814A and 814B, respectively. Current flows from source regions 810A and 810B through the channel regions underlying gates 812A and 812B and then vertically downward through isolated region 806 to N+ buried layer 804. The current flows laterally in N+ buried layer 804 to isolation structure 802 and then upward in isolation structure 802 to a metal contact (not shown) on the surface of N-epi layer 42.

P substrate 40 is grounded by means of a P+ sinker 840, formed in accordance with this invention. A P+ region 842 ensures a good ohmic contact between P+ sinker 840 and P substrate 40. Quasi-vertical NMOS 80 is isolated from P substrate 40 so long as the drain potential of NMOS 80 is positive with respect to ground.

FIG. 8B is a top view of NMOS 80. FIG. 8A is taken at cross section 8A-8A shown in FIG. 8B. As indicated by the break in the substrate 40 and N-epi layer 42 in FIG. 8A, a number of NMOS devices similar to NMOS 80 could be fabricated inside N+ isolation structure 802. FIG. 8C is an alternative plan view of NMOS 80, showing a number of unit cells, each including a source region 810 and a P+ body contact region 811, and all being surrounded by isolation structure 802. A polysilicon gate 812 overlies the spaces between the unit cells and a channel region of the P-body of each cell (not shown).

Although the present invention is illustrated in connection with specific embodiments for instructional purposes, the present invention is not limited thereto. Various adaptations and modifications may be made without departing from the scope of the invention. For example, although the embodiments described above generally include an epitaxial layer formed on top of a semiconductor substrate, it will be understood that other embodiments do not contain an epitaxial layer; rather, the trench is formed in a layer of first conductivity type, which may be formed by implantation and/or diffusion, overlying a layer of a second conductivity type. Therefore, the spirit and scope of the appended claims should not be limited to the foregoing description.

We claim:

1. A process of fabricating a semiconductor structure, said process comprising:
providing a semiconductor substrate;
growing an epitaxial layer on said substrate;
forming a mask layer on a surface of said epitaxial layer;
forming an opening in said mask layer;
etching said epitaxial layer through said opening in said mask layer to form a trench;
continuing said etching until a floor of said trench is located in said substrate;
forming an oxide layer on a sidewall and floor of said trench;
removing a first portion of said oxide layer from said floor of said trench while leaving a second portion of said oxide layer on said sidewall of said trench;
depositing a layer of polysilicon layer into said trench, said polysilicon layer being doped with material of a first conductivity type;
removing a portion of said polysilicon layer such that a top surface of said polysilicon layer is located at or below a top surface of said epitaxial layer; and
forming a metal contact in electrical contact with said top surface of said polysilicon layer.

2. The process of claim 1 wherein said epitaxial layer is doped with material of a second conductivity type opposite to said first conductivity type.

3. The process of claim 2 wherein said substrate is doped with material of said first conductivity type.

4. The process of claim 2 wherein said substrate layer is doped with material of said second conductivity type, said process further comprising forming a region of said first conductivity type in said substrate, said etching comprising etching into said region of said first conductivity type in said substrate.
